(19) United States
(12) Patent Application Publication
(10) Pub. No.: US 2024/0128151 A1
(43) Pub. Date: Apr. 18, 2024

(54) PACKAGE STRUCTURE

(71) Applicant: HON HAI PRECISION INDUSTRY CO., LTD., New Taipei City (TW)

(72) Inventors: Chun-Yen PENG, New Taipei City (TW); Kuo-Bin HONG, New Taipei City (TW); Shih-Chen CHEN, New Taipei City (TW); Hao-Chung KUO, New Taipei City (TW)

(21) Appl. No.: 18/488,026

(22) Filed: Oct. 16, 2023

(30) Foreign Application Priority Data
Oct. 17, 2022 (TW) 111139305

(51) Int. Cl. H01L 23/367; H01L 23/00

(52) U.S. Cl. CPC H01L 23/3677; H01L 24/16; H01L 24/32; H01L 24/73; H01L 2224/16225; H01L 2224/32225; H01L 2224/32245; H01L 2224/73203; H01L 2924/00

(57) ABSTRACT

A package structure includes a bonding substrate, an integrated circuit, and a heat sink metal. The integrated circuit includes an active region facing the bonding substrate. The heat sink metal is located between the bonding substrate and the active region of the integrated circuit. The heat sink metal is electrically insulated with the integrated circuit.

### CROSS-REFERENCE TO RELATED APPLICATION

This application claims priority to Taiwan Application Serial Number 111139305, filed Oct. 17, 2022, which is herein incorporated by reference in its entirety.

### BACKGROUND

### Field of Invention

The present invention relates to a package structure.

### Description of Related Art

A common method in a heat sink design of a package structure is using bumps that interconnecting the substrate and chips as heat sink structures. However, holes formed in the metal material due to electrochemical reaction and alloy reaction. In the welding process, bubbles may be formed in the insulating layer. Therefore, defects formed in the metal material used for conduction based on the reasons described above will cause metal fatigue.

Furthermore, such design has many disadvantages such as the coefficient of thermal expansion difference of heterojunction structure, broken solder bump, complicated layout design for bonding metal material, and planarization of bump surface, etc.

Accordingly, it is still a development direction for the industry to provide a package structure that can solve the problems mentioned above.

### SUMMARY

One aspect of the present invention is a package structure.

In one embodiment, the package structure includes a bonding substrate, an integrated circuit, and a heat sink metal. The integrated circuit includes an active region facing the bonding substrate. The heat sink metal is located between the bonding substrate and the active region of the integrated circuit. The heat sink metal is electrically insulated with the integrated circuit.

Another aspect of the present invention is a package structure.

In one embodiment, the package structure includes a bonding substrate, an integrated circuit, a heat sink metal, and an insulating layer. The integrated circuit includes an active region facing the bonding substrate. The heat sink metal is located between the bonding substrate and the active region of the integrated circuit. The insulating layer is located between the heat sink metal and the integrated circuit. The insulating layer wraps the heat sink metal and separates the heat sink metal from the active region.

Another aspect of the present invention is a package structure.

In one embodiment, the package structure includes a bonding substrate, an integrated circuit, and multiple heat sink metals. The integrated circuit includes an active region facing the bonding substrate. The bonding substrate includes a top surface facing the integrated circuit. The heat sink metals are located between the bonding substrate and the active region of the integrated circuit. The heat sink metals are disposed on the top surface of the bonding substrate. The heat sink metals are electrically insulated with the integrated circuit.

In aforementioned embodiments, since the heat sink metal is not used for electrical connection, electrochemical reaction and metal fatigue of the heat sink metals after thermo-shock test can be avoided. The heat sink metals correspond to the active elements in position along the vertical direction. Since the heat sink metals are not used for electrically connecting the bonding substrate and the integrated circuit, the arrangement density of the heat sink metals is higher. Therefore, it can effectively improve thermal conducting efficiency and enhance heat sink effect.

### BRIEF DESCRIPTION OF THE DRAWINGS

The invention can be more fully understood by reading the following detailed description of the embodiment, with reference made to the accompanying drawings as follows:

FIG. 1 is a side view of a package structure according to one embodiment of the present disclosure.

FIG. 2 is a stereoscopic view of a package structure according to one embodiment of the present disclosure.

FIG. 3 is an enlarged view of the bonding substrate, the heat sink metals and the insulating layer in FIG. 2.

FIG. 4 is a stereoscopic view of a package structure according to another embodiment of the present disclosure, and the integrated circuit is omitted.

FIG. 5 is a side view of a package structure according to another embodiment of the present disclosure.

FIG. 6 is a side view of a package structure according to another embodiment of the present disclosure.

FIG. 7 is a temperature difference simulation of the package structures of various embodiments.

FIG. 8 is a simulation of thickness and temperature of the package structures of various embodiments.

FIG. 9 is a relation diagram between thickness ratio and temperature of a heat sink metal according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

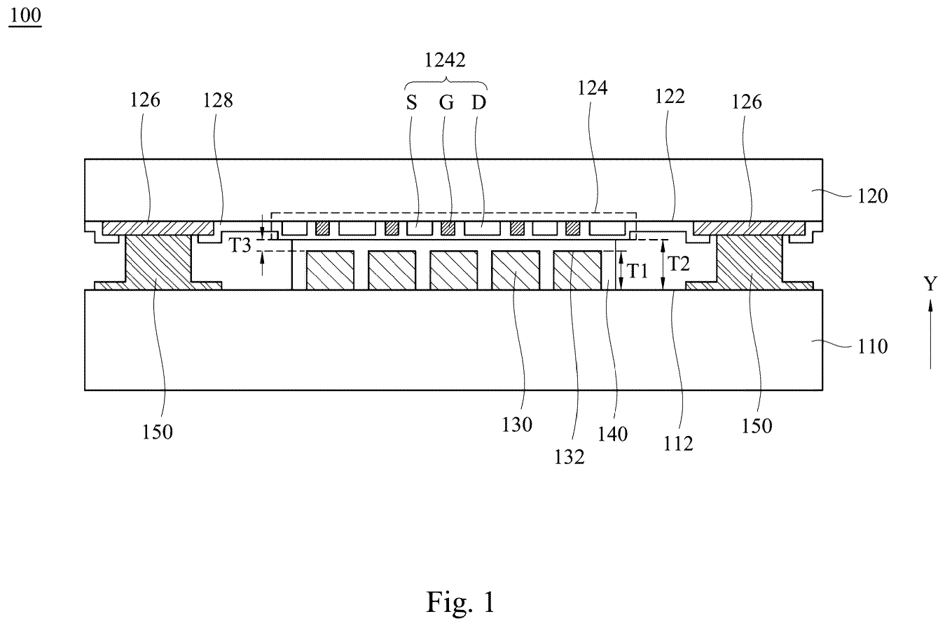

FIG. 1 is a side view of a package structure 100 according to one embodiment of the present disclosure. The package structure 100 includes a bonding substrate 110, an integrated circuit 120, and heat sink metals 130. The integrated circuit 120 and the bonding substrate 110 are piled along a vertical direction Y. The integrated circuit 120 includes an active region 124 facing the bonding substrate 110. The active region 124 is located on a top surface 122 of the bonding substrate 110 facing the bonding substrate 110. The heat sink metals 130 are located between the bonding substrate 110 and the active region 124 of the integrated circuit 120. The heat sink metals 130 are disposed on a top surface 112 of the bonding substrate 110 facing the bonding substrate 110. The heat sink metals 130 contact the top surface 112 of the bonding substrate 110, and the heat sink metals 130 do not contact the integration circuit 120. In other words, the heat sink metals 130 are electrically insulated with the integrated circuit 120, and the heat sink metals 130 are not the structure used to interconnect the bonding substrate 110 and the integrated circuit 120.

The heat sink metals 130 are heat sink structures of the package structure 100 and are configured to conduct heat source from the active region 124. The heat sink metals 130 can be applied in various package structures such as a heterojunction heat sink package structure, a high density heat source heat sink package structure, and 3D-IC package structure.

For example, the material of the bonding substrate 110 is AlN submount. The base material of the integrated circuit 120 is silicon carbide substrate or sapphire substrate. The material of the heat sink metals 130 is Au, Cu, or other metal material with good conductivity.

In the present embodiment, the package structure 100 further includes an insulating layer 140 located between the heat sink metals 130 and the integrated circuit 120. The insulating layer 140 surrounds the heat sink metals 130. The insulating layer 140 fills the space between the active region 124 of the integrated circuit 120, the heat sink metals 130 and the bonding substrate 110. In other words, the insulating layer 140 wraps the entire heat sink metals 130 to separate the heat sink metals 130 from the active region 124, and the insulating layer 140 connects the integrated circuit 120.

In one embodiment, the insulating layer 140 is a underfill that enables the bonding substrate 110 to be bonded firmly with the integrated circuit 120 and electrically insulate the integrated circuit 120 and the heat sink metals 130. In other embodiments, the insulating layer 140 is a thermal interface material (TIM) that can improve the thermal conducting efficiency. In the present embodiment, the heat sink metals 130 do not used for electrical connection, and therefore the material selectivity of the insulating layer 140 won't be limited due to the coefficient of thermal expansion difference of heterojunction structure.

As shown in FIG. 1, the integrated circuit 120 further comprises a conductive pad 126 and a protection layer 128 disposed on the top surface 122. The conductive pad 126 is located outside the active region 124. The active region 124 includes multiple active elements 1242. The protection layer 128 covers the active elements 1242 of the active region 124 and the conductive pad 126. The protection layer 128 and the insulating layer 140 can electrically insulate the integrated circuit 120 and the heat sink metals 130. In the present embodiment, the insulating layer 140 contacts the protection layer 128, the heat sink metals 130, and the top surface 112 of the bonding substrate 110.

The package structure 100 further includes an electrical connecting element 150. A portion of the conductive pad 126 is exposed from the protection layer 128. The electrical connecting element 150 is configured to electrically connect the conductive pad 126 of the integrated circuit 120 and the bonding substrate 110. For example, the electrical connecting element 150 can be metal bump, metal cylinder. The integrated circuit 120 of the package structure 100 is electrically connected with the bonding substrate 110 through flip chip bonding method.

In the present embodiment, the insulating layer 140 is located between the active region 124 and the bonding substrate 110, but the present disclosure is not limited thereto. In other embodiments, the underfill or thermal interface material can extend outside the active region 124 and surrounds the electrical connecting element 150.

Five heat sink metals 130 are exemplarily illustrated in FIG. 1, but the present disclosure is not limited thereto. The heat sink metals 130 correspond to the active element 1242 in position along the vertical direction Y. Specifically speaking, the active element 1242 includes source S, drain D, and gate G. Heat source of the active region 124 comes from the gate G. Therefore, the arrangement of the heat sink metals 130 are designed based on the distribution of the gate G of the active element 1242. For example, an orthogonal projection of the gate G on the bonding substrate 110 is within a range of an orthogonal projection of the heat sink metals 130 on the bonding substrate 110. In some other embodiments, the package structure 100 can have one single heat sink metal 130 located between the entire active region 124 and the bonding substrate 110.

In a design of which a metal bump electrically connecting the bonding substrate 110 and the integrated circuit 120 is used as the heat sink structure, an extra metal layer is necessary to connect the integrated circuit 120 and the metal bump. In addition, when the metal bump is bonded with the integrated circuit 120 and the bonding substrate 110 simultaneously, the metal bump having smaller top surface has poor heat sink effect. In other words, the heat sink metals 130 electrically insulated with the integrated circuit 120 are used as heat sink structure in the present disclosure. As such, the layout design of the integrated circuit 120 can be simplified and the heat sink effect can be improved.

In general, alloy reaction occurs in the metal material used as electrical connecting element due to electrochemical reaction. Therefore, holes formed in the metal material. In the welding process, bubbles may be formed in the insulating layer 140. Therefore, defects formed in the metal material used for conduction based on the reasons described above cause metal fatigue. Since the heat sink metals 130 of the present disclosure are not used for electrical connection, electrochemical reaction and metal fatigue of the heat sink metals 130 after thermo-shock test can be avoided. In addition, since the heat sink metals 130 and the integrated circuit 120 are not electrically connected, there is no need to perform planarization process on the surface 132 of the heat sink metals 130 to improve bonding reliability. Therefore, manufacturing process of the package structure 100 can be simplified.

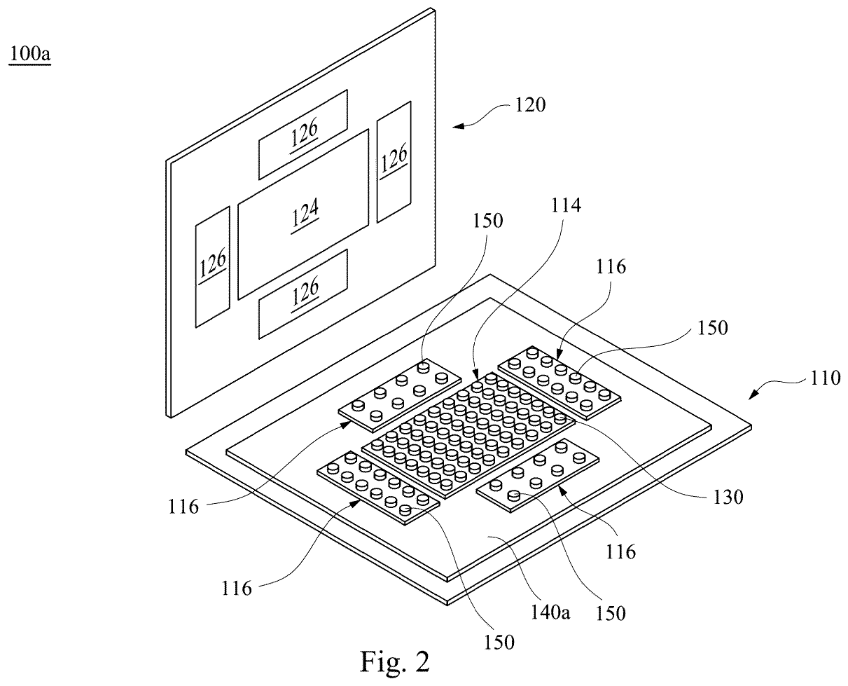

FIG. 2 is a stereoscopic view of a package structure 100a according to one embodiment of the present disclosure. The bonding substrate 110 is separated from the integrated circuit 120 in FIG. 2. The integrated circuit 120 in FIG. 2 includes an active region 124 and four conductive pads 126, and the conductive pads 126 are respectively located at four sides of the active region 124.

The conductive pads 126 are electrically connected to the source S, the drain D, and the gate G (see FIG. 1) through traces (not shown). The heat sink metals 130 distribute in a region 114 corresponding to the active region 124. The electrical connecting elements 150 distribute in regions 116, and the regions 116 correspond to the positions of the conductive pads. The regions 116 are presented at four sides of the region 114, and the positions of the electrical connecting elements 150 correspond to the positions of the conductive pads 126. In the present embodiment, the insulating layer 140a covers the heat sink metals 130 and the electrical connecting elements 150. In other words, the insulating layer 140a covers the region 114 and the regions 116, but the present disclosure is not limited thereto. The insulating layer 140a at least covers the space between the heat sink metals 130 and the active region 124.

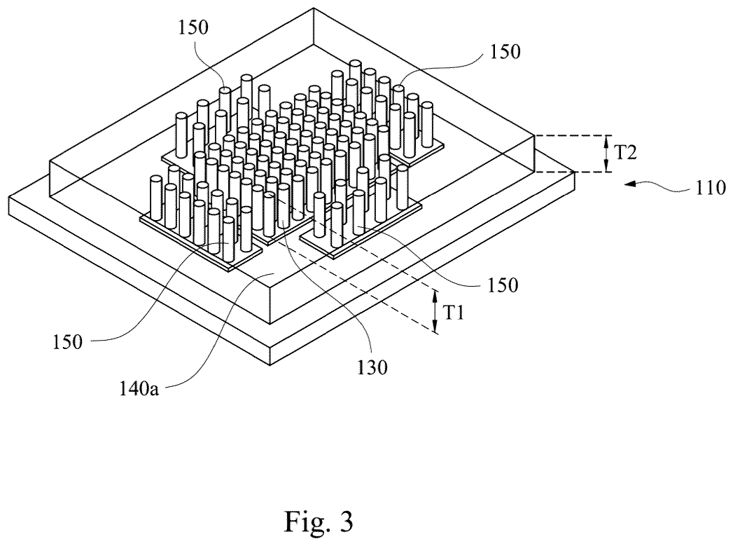

FIG. 3 is an enlarged view of the bonding substrate 110, the heat sink metal 130 and the insulating layer 140a in FIG. 2. In the present embodiment, the heat sink metals 130 have a circular cylinder shape, and the heat sink metals 130 are arrange regularly. In the present embodiment, each of the heat sink metals 130 have the same shape and size, but the present disclosure is not limited thereto. Specifically, since the heat source of the active region 124 mainly comes from the gate G, widths of the heat sink metals 130 can be determined based on heat expansion range.

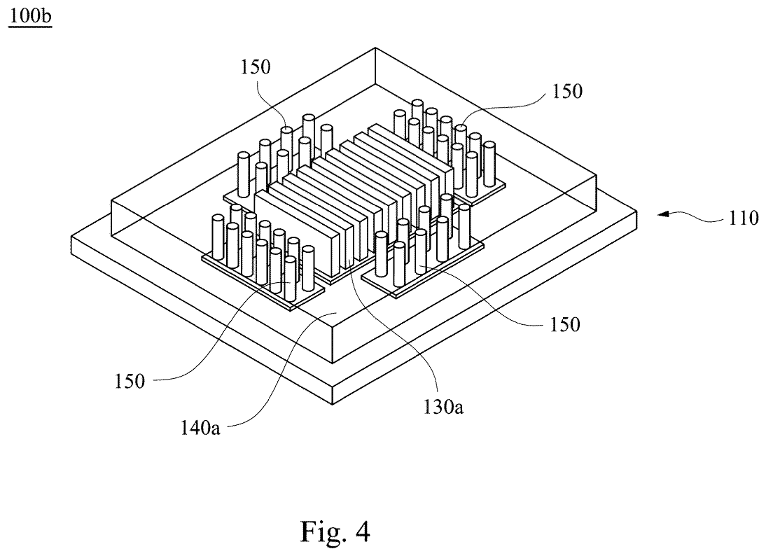

FIG. 4 is a stereoscopic view of a package structure 100b according to another embodiment of the present disclosure, and the integrated circuit 120 is omitted. The heat sink metals 130a of the package structure 100b have a strip shape. The heat sink metals 130a are arranged regularly and in a grid shape. Each of the heat sink metals 130 have the same shape and size, but the present disclosure is not limited thereto.

In generally, an interval between the active elements 1242 of the integrated circuit 120 having larger current loading is narrower. Since the heat sink metals 130a are not used for electrically connecting the bonding substrate 110 and the integrated circuit 120, the arrangement density of the heat sink metals 130a is higher. For example, the gate g of the active element 1242 are arranged in a finger shape. Therefore, the width of the gate G in FIG. 1 is narrower and the arrangement density is higher. As such, the intervals of the heat sink metals 130a having grid shape are narrow, and the heat sink metals 130a are disposed correspond to the active elements 1242.

For example, in some embodiments, the intervals between the electrical connecting elements 150 are 2-3 um and the intervals between the heat sink metals 130a can be reduced to smaller than 1 um. In other words, the arrangement density of the heat sink metals 130a is close to the design rule of the pitch of the active elements 1242. As a result, the heat sink metals 130a can effectively improve thermal conducting efficiency and enhance heat sink effect.

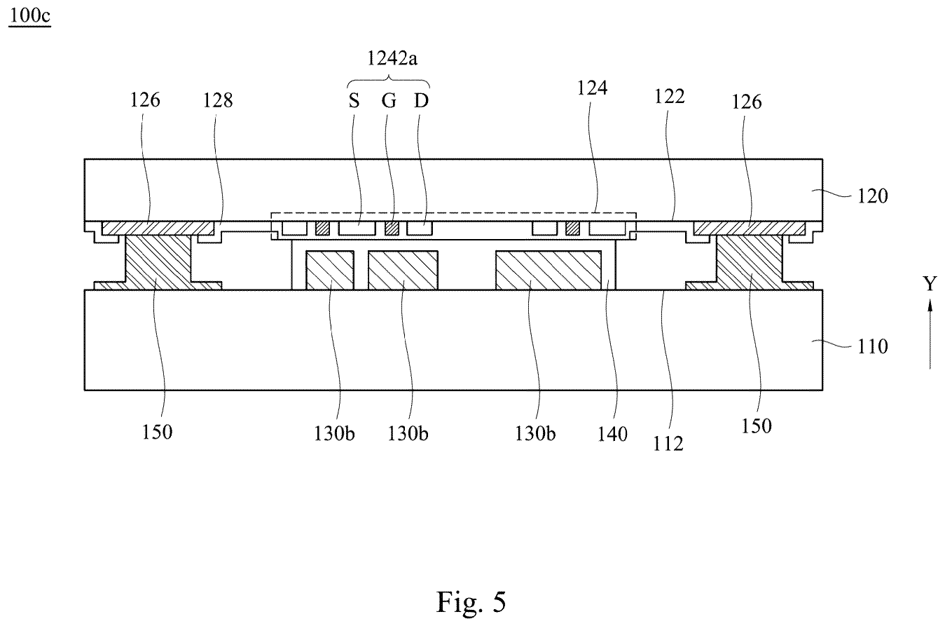

FIG. 5 is a side view of a package structure 100c according to another embodiment of the present disclosure. The package structure 100c is similar to the package structure 100 in FIG. 1, and the difference is that the heat sink metals 130b are arranged irregularly. For example, the active elements 1242a in this embodiment are arranged irregularly, and the heat sink metals 130b correspond to the active elements 1242a in position along the vertical direction Y. As described above, the widths of the heat sink metals 130b can be determined based on heat expansion range. Therefore, the sizes of the heat sink metals 130b can be different. In some embodiments, the shapes of the heat sink metals 130b can be different as well.

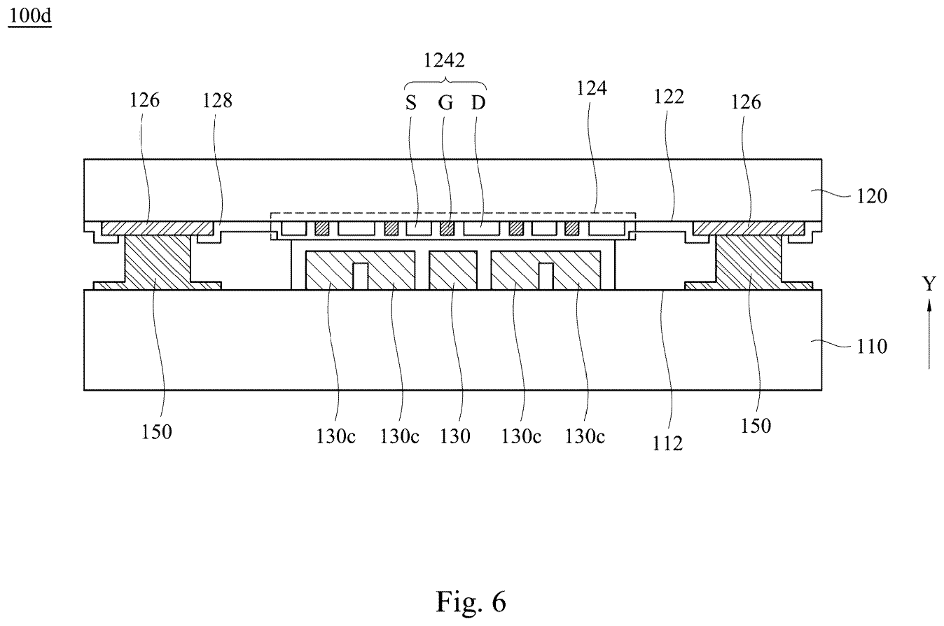

FIG. 6 is a side view of a package structure 100d according to another embodiment of the present disclosure. The package structure 100d is similar to the package structure 100 in FIG. 1, and the difference is that heat sink metals 130c of the package structure 100d are not totally separated from each other. For example, two of the heat sink metals 130c at the left had side in FIG. 6 are partially connected together, and two of the heat sink metals 130c at the right hand side are partially connected together. Since the heat sink metals 130c are not used for electrical connection, the heat sink metals 130c still have the heat sink function when connected together.

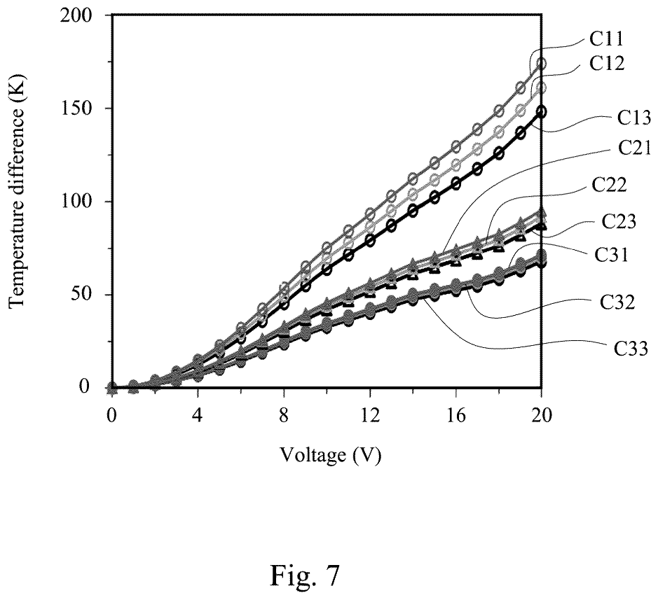

FIG. 7 is a temperature difference simulation of the package structures of various embodiments. Data of the curve C11, the curve C12, and the curve C13 are derived by measuring temperatures when the top surface 122 of the integrated circuit 120 faces upward (that is, the integrated circuit bonded with the wire bonding method). The data of the curve C11, the curve C12, and the curve C13 represent the relation between the voltage and the temperature difference between the package structure and ambient temperature when the ambient temperatures are 360K, 330K, 300K, respectively. It can be seen from the curves C11-C13 that the temperature raised up to about 150K to 175 k when the voltages increase.

Reference is made to FIG. 2 and FIG. 7, the data of the curve C21, the curve C22, and the curve C23 are derived by measuring the temperature differences of the package structure 100 shown in FIG. 2. The data of the curve C21, the curve C22, and the curve C23 represent the relation between the voltage and the temperature difference when the ambient temperatures are 360K, 330K, 300K, respectively. In the present embodiment, the integrated circuit 120 of the package structure 100 includes GaN High electron mobility Transistor (HEMT). It can be seen from the curves C21-C23 that the temperature raised up to about 75K to 100k when the voltages increase.

Data of the curve C31, the curve C32, and the curve C33 are derived by measuring temperatures of the package structure 100b having heat sink metals 130a in FIG. 4. The data of the curve C31, the curve C32, and the curve C33 represent the relation between the voltage and the temperature difference when the ambient temperatures are 360K, 330K, 300K, respectively. It can be seen from the curves C31-C33 that the temperature merely raised up to about 50K to 75k when the voltages increase.

Based on the data above, It can be seen that the heat sink effect can be effectively improved by disposed the heat sink metals 130 correspond to the active region in position and by insulating the heat sink metals 130 from the active region 124.

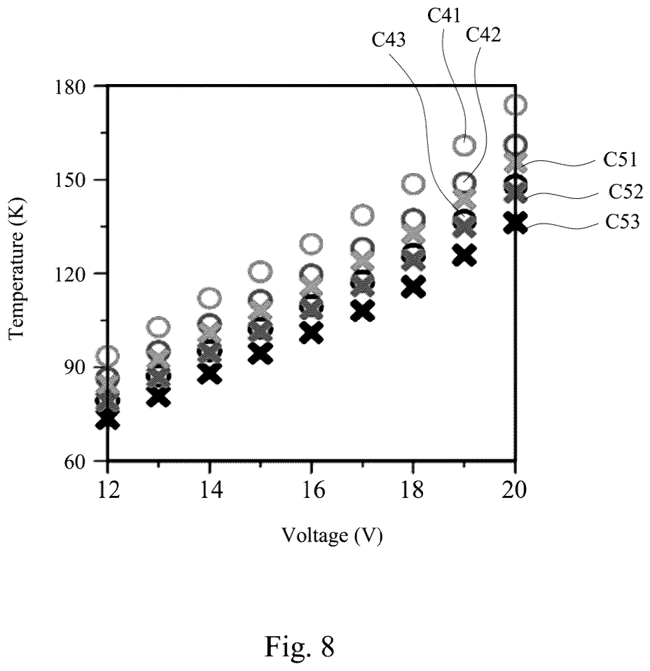

FIG. 8 is a simulation of thickness and temperature of the package structures of various embodiments. Data of the curve C41, the curve C42, and the curve C43 represent the temperature difference of 10 integrated circuits 120 whose thickness is 100 um when the ambient temperatures are 360K, 330K, 300K, respectively. Data of the curve C51, the curve C52, and the curve C53 represent the temperature difference of 10 integrated circuits 120 whose thickness is 300 um when the ambient temperatures are 360K, 330K, 300K, respectively. The thicker the substrates of the integrated circuits are, the lower the thermal resistance of a heat sink path is. Therefore, the heat sink effect is better.

Reference is made to FIG. 1. The heat sink metals 130 have a thickness T1, and the insulating layer 140 has a thickness T2. The heat sink metals 130 have a surface 132 facing the integrated circuit 120. A portion of the insulating layer 140 located above the surface 132 has a thickness T3. A ratio between the thickness T3 and the thickness T1 influence the heat sink effect of the package structure 100.

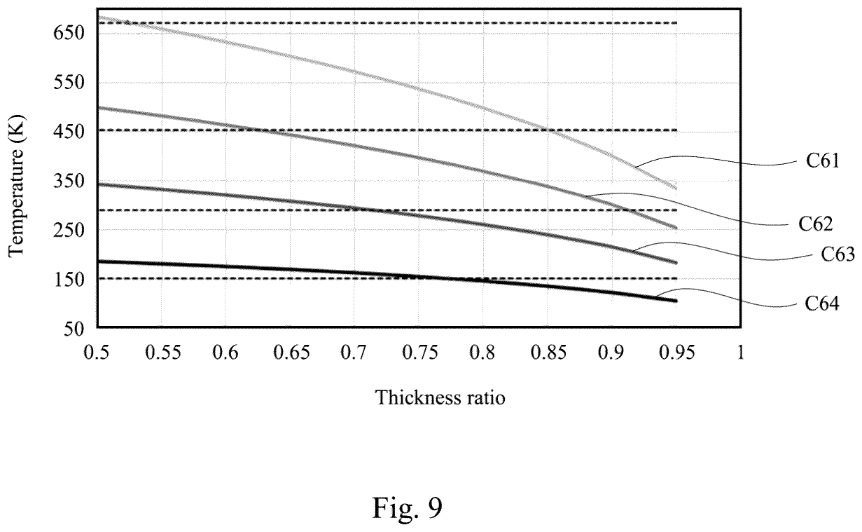

FIG. 9 is a relation diagram between thickness ratio and temperature of a heat sink metal according to one embodiment of the present disclosure. Reference is made to FIG. 1 and FIG. 9 simultaneously. In the present embodiment, a underfill is used as the material of the insulating layer 140. The curve C61, the curve C62, the curve C63, and the curve C64 represent relations between the temperature and the thickness ratio measured form the package structure of the present disclosure when the voltage are 20V, 16V, 12V, and 8V, respectively. Definition of thickness ratio is thickness T2 over thickness T1 shown in FIG. 1. The dashed lines correspond to 660K, 450K, 290K, and 150K represent the temperatures measured when the top surface 122 of the integrated circuit 120 faces upward (that is, the integrated circuit bonded with the wire bonding method) and when the voltages are 20V, 16V, 12V, and 8V, respectively.

It can be seen from FIG. 9 that when the thickness of the heat sink metals 130 is thicker (the thickness ratio is higher), the temperatures under different ambient environment all show a downward trend. Reference is made to FIG. 1 and FIG. 9 simultaneously. Since the thermal conductivity of the underfill is smaller than the thermal conductivity of the metal material, better heat sink effect and insulating effect can be achieved simultaneously by disposing the underfill on the heat sink metals 130 and by reducing the thickness T3 of the underfill above the heat sink metals 130 through lamination process.

In summary, since the heat sink metal is not used for electrical connection, electrochemical reaction and metal fatigue of the heat sink metal after thermo-shock test can be avoided. The heat sink metals correspond to the active elements in position along the vertical direction. Since the heat sink metals are not used for electrically connecting the bonding substrate and the integrated circuit, the arrangement density of the heat sink metals is higher. Therefore, it can effectively improve thermal conducting efficiency and enhance heat sink effect. There is no need to use an extra metal layer to electrically connect the heat sink metal by disposed a heat sink metal that is electrically insulated from the integrated circuit. As such, the layout design of the integrated circuit can be simplified and the heat sink effect can be improved. In addition, there is no need to perform planarization process on the surface of the heat sink metal to improve bonding reliability. Therefore, manufacturing process of the package structure can be simplified.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A package structure, comprising:
a bonding substrate;
an integrated circuit comprising an active region facing the bonding substrate; and
a heat sink metal located between the bonding substrate and the active region of the integrated circuit, wherein the heat sink metal is electrically insulated with the integrated circuit.

2. The package structure of claim 1, wherein the bonding substrate comprises a top surface facing the integrated circuit, and the heat sink metal is disposed on the top surface.

3. The package structure of claim 2, further comprising:
an insulating layer located between the heat sink metal and the integrated circuit, wherein the insulating layer is a underfill.

4. The package structure of claim 1, further comprising:
an insulating layer located between the heat sink metal and the integrated circuit, wherein the insulating layer is thermal interface material.

5. The package structure of claim 1, wherein the active region of the integrated circuit includes a plurality of active elements, a number of the at least one heat sink metal is plural, and the heat sink metals correspond to the active elements in position along a vertical direction.

6. The package structure of claim 1, wherein the heat sink metal has a circular cylinder shape.

7. The package structure of claim 1, wherein the heat sink metal has a strip shape.

8. The package structure of claim 1, wherein a number of the at least one heat sink metal is plural, and the heat sink metals are arranged regularly.

9. The package structure of claim 1, wherein a number of the at least one heat sink metal is plural, and the heat sink metals are arranged irregularly.

10. The package structure of claim 1, wherein the integrated circuit and the bonding substrate are piled along a vertical direction.

11. A package structure, comprising:
a bonding substrate;
an integrated circuit comprising an active region facing the bonding substrate;
at least one heat sink metal located between the bonding substrate and the active region of the integrated circuit; and
an insulating layer located between the heat sink metal and the integrated circuit, wherein the insulating layer wraps the heat sink metal and separate the heat sink metal from the active region.

12. The package structure of claim 11, wherein the bonding substrate comprises a top surface facing the integrated circuit, and the heat sink metal is disposed on the top surface.

13. The package structure of claim 11, wherein the insulating layer is a underfill or thermal interface material.

14. The package structure of claim 11, wherein the active region of the integrated circuit includes a plurality of active elements, a number of the at least one heat sink metal is plural, and the heat sink metals correspond to the active elements in position along a vertical direction.

15. The package structure of claim 11, wherein the heat sink metal has a circular cylinder shape or a strip shape.

16. A package structure, comprising:
a bonding substrate;
an integrated circuit comprising an active region facing the bonding substrate, wherein the bonding substrate comprises a top surface facing the integrated circuit; and
a plurality of heat sink metals located between the bonding substrate and the active region of the integrated circuit, wherein the heat sink metals are disposed on the top surface of the bonding substrate, and the heat sink metals are electrically insulated with the integrated circuit.

17. The package structure of claim 16, further comprises:
an insulating layer located between the heat sink metals and the integrated circuit, wherein the insulating layer is a underfill or thermal interface material.

18. The package structure of claim 16, wherein the active region of the integrated circuit comprises a plurality of active elements, and the heat sink metals correspond to the active elements in position along a vertical direction.

19. The package structure of claim 16, wherein the integrated circuit and the bonding substrate are piled along a vertical direction.

20. The package structure of claim 16, wherein the heat sink metals are arranged in a grid shape.
